(19) United States
(12) Patent Application Publication
(10) Pub. No.: US 2026/0071315 A1
(43) Pub. Date: Mar. 12, 2026

(54) MASK FRAME ASSEMBLY MANUFACTURING APPARATUS AND MASK FRAME ASSEMBLY MANUFACTURING METHOD USING THE SAME

(71) Applicant: Samsung Display Co., Ltd., YONGIN-SI (KR)

(72) Inventors: KYONGHO HONG, Yongin-si (KR); INWOO KIM, Yongin-si (KR); HEESEAK NOH, Yongin-si (KR); HYUN MIN LEE, Yongin-si (KR); SUCKHO KANG, Yongin-si (KR); BONG SU KIM, Yongin-si (KR); WANSUB KIM, Yongin-si, Gyeonggi-do (KR); TAEWOO KIM, Yongin-si (KR); SUNG JIN NA, Yongin-si (KR); CHANG-KON PARK, Yongin-si (KR); HYOGEUN LEE, Yongin-si (KR); DAUN JO, Yongin-si (KR); GANGUI HONG, Yongin-si (KR)

(21) Appl. No.: 19/181,455

(22) Filed: Apr. 17, 2025

(30) Foreign Application Priority Data
Sep. 9, 2024 (KR) 10-2024-0122617

(51) Int. Cl. C23C 14/04; H10K 59/12; H10K 71/16

(52) U.S. Cl. CPC C23C 14/042; H10K 59/1201; H10K 71/166

(57) ABSTRACT

A mask frame assembly manufacturing apparatus includes: a mask stage including a plurality of air holes, wherein a mask frame is disposed on the mask stage; an air injection module injecting air toward the mask frame through the air holes; and a lifting module that ascends or descends in a height direction of the mask stage to adjust a separation distance between the mask stage and the mask frame.

### CROSS-REFERENCE TO RELATED APPLICATION

This application claims priority under 35 U.S.C. § 119 to Korean Patent Application No. 10-2024-0122617, filed on Sep. 9, 2024, in the Korean Intellectual Property Office, the disclosure of which is incorporated by reference herein in its entirety.

### TECHNICAL FIELD

One or more embodiments of the present invention relate to a mask frame assembly manufacturing apparatus and a mask frame assembly manufacturing method using the same.

### DISCUSSION OF THE RELATED ART

Among various display apparatuses, an organic light-emitting display apparatus has gained attention as a next-generation display device due to its superior visual performance, including, for example, wide viewing angles, high contrast ratios, and fast response times.

Typically, an organic light-emitting display apparatus includes a first electrode and a second electrode positioned opposite each other, with an intermediate layer formed between them. The intermediate layer includes an emission layer, which is responsible for generating light when an electric current is applied. Additionally, the intermediate layer may include other functional layers, such as a hole injection layer, hole transport layer, electron transport layer, and electron injection layer, which facilitate efficient charge transport. Here, the electrodes and the intermediate layer may be formed in various ways, one of which is an independent deposition method. To manufacture an organic light-emitting display apparatus by an independent deposition method, a fine metal mask (FMM) having a pattern that is the same as that of an organic layer, etc. that is to be formed is in close contact with a surface of a substrate, on which the organic layer, etc. is to be formed, and then, a material of the organic layer, etc. is deposited on the surface to form the organic layer with a certain pattern.

### SUMMARY

According to an embodiment of the present inventive concept, a mask frame assembly manufacturing apparatus includes: a mask stage including a plurality of air holes, wherein a mask frame is disposed on the mask stage; an air injection module injecting air toward the mask frame through the air holes; and a lifting module that ascends or descends in a height direction of the mask stage to adjust a separation distance between the mask stage and the mask frame.

In an embodiment of the present inventive concept, the air injection module separates edge portions of the mask frame from the mask stage.

In an embodiment of the present inventive concept, the lifting module separates corner portions of the mask frame from the mask stage.

In an embodiment of the present inventive concept, the lifting module includes: a lifting body configured to move in the height direction of the mask stage and to extend through the mask stage; and a contact portion that is rotatably coupled to the lifting body and comes into contact with the mask frame.

In an embodiment of the present inventive concept, the lifting module is of a plurality of lifting modules, wherein the plurality of lifting modules support a plurality of points, of the mask frame, that are symmetrical to each other with respect to a virtual reference line passing through a center of the mask frame.

In an embodiment of the present inventive concept, the plurality of lifting modules simultaneously separate the plurality of points of the mask frame from the mask stage by predetermined distances.

In an embodiment of the present inventive concept, the mask frame assembly manufacturing apparatus further includes: a driver having a driving motor connected to the plurality of lifting modules and controlling the ascending and descending of the lifting modules.

In an embodiment of the present inventive concept, the plurality of the air holes are provided in the mask stage, and are arranged with first intervals along a lengthwise direction of the mask stage and with second intervals along a width direction of the mask stage.

In an embodiment of the present inventive concept, the air injection module lifts a plurality of first points of the mask frame by a first height, and the lifting module lifts a plurality of second points of the mask frame by a second height.

In an embodiment of the present inventive concept, the first height is different from the second height.

In an embodiment of the present inventive concept, the mask frame includes: a first frame body to which a mask sheet is welded; and a second frame body supporting the first frame body, wherein the lifting module lifts a peripheral region of the second frame body, on which the first frame body is not disposed.

According to an embodiment of the present inventive concept, a mask frame assembly manufacturing method includes: disposing a mask frame on a mask stage; and obtaining a mask frame assembly by welding a plurality of mask sheets to the mask frame, wherein the obtaining of the mask frame assembly includes: adjusting a separation distance between the mask stage and the mask frame by using at least one of an air injection module or a lifting module; and welding a first mask sheet of the plurality of mask sheets to the mask frame.

In an embodiment of the present inventive concept, the adjusting of the separation distance includes: separating the mask frame from the mask stage by injecting air from the air injection module toward the mask frame; and separating the mask frame from the mask stage by moving the lifting module in a height direction of the mask stage.

In an embodiment of the present inventive concept, the air injection module separates edge portions of the mask frame from the mask stage.

In an embodiment of the present inventive concept, the lifting module separates corner portions of the mask frame from the mask stage.

In an embodiment of the present inventive concept, the lifting module includes: a lifting body configured to move in a height direction of the mask stage and to extend through the mask stage; and a contact portion that is rotatably coupled to the lifting body and comes into contact with the mask frame.

In an embodiment of the present inventive concept, the lifting module is of a plurality of the lifting modules, wherein the plurality of lifting modules support a plurality of points, of the mask frame, that are symmetrical to each other with respect to a virtual reference line passing through a center of the mask frame.

In an embodiment of the present inventive concept, the air injection module lifts a plurality of first points of the mask frame by a first height, and the lifting module lifts a plurality of second points of the mask frame by a second height.

In an embodiment of the present inventive concept, the first height is different from the second height.

In an embodiment of the present inventive concept, the obtaining of the mask frame assembly includes: re-adjusting a separation distance between the mask stage and the mask frame by using at least one of the air injection module or the lifting module; and welding a second mask sheet of the plurality of mask sheets to the mask frame, to be adjacent to the first mask sheet of the plurality of mask sheets.

### BRIEF DESCRIPTION OF THE DRAWINGS

The above and other aspects, and features of certain embodiments of the present invention will be more apparent by describing in detail embodiments thereof, with reference to the accompanying drawings, in which:

FIG. 1 is a perspective view of a mask frame and a mask sheet according to an embodiment of the present invention;

FIG. 2 is a side view schematically showing a mask frame assembly manufacturing apparatus according to an embodiment of the present invention;

FIG. 3 is a plan view of a mask stage of FIG. 2;

FIGS. 4 and 5 are perspective views schematically illustrating processes of manufacturing a mask frame assembly of FIG. 1;

FIG. 6 is a diagram conceptually showing a process of welding a first mask sheet to the mask frame of FIG. 1;

FIG. 7 is an enlarged view showing a region in FIG. 6;

FIGS. 8 and 9 are diagrams conceptually showing a process of welding a second mask sheet to the mask frame of FIG. 1;

FIG. 10 is a diagram schematically showing a deposition of a deposition layer on a substrate by using the mask frame assembly of FIG. 1;

FIG. 11 is a cross-sectional view of a sub-pixel in an organic light-emitting display apparatus in which an emission layer is deposited on a substrate of FIG. 10;

FIG. 12 is a block diagram of an electronic device according to an embodiment of the present invention;

FIG. 13 illustrates schematic views of individual electronic devices according to various embodiments of the present invention; and

FIG. 14 is a block diagram illustrating an electronic device according to an embodiment of the present invention.

### DETAILED DESCRIPTION OF THE EMBODIMENTS

Embodiments of the present invention will now be described more fully with reference to the accompanying drawings. It is to be understood that the present invention may be embodied in different forms and thus should not be construed as being limited to the embodiments set forth herein. It is to be understood that like reference numerals may refer to like elements throughout the specification and drawings, and thus, redundant descriptions may be omitted. As used herein, the term “and/or” includes any and all combinations of one or more of the associated listed items. Expressions such as “at least one of,” when preceding a list of elements, modify the entire list of elements and do not modify the individual elements of the list.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

It will be understood that singular expressions include plural expressions, unless the context clearly indicates otherwise.

The singular forms “a,” “an” and “the” in the specification of the embodiments, in particular, claims, may be intended to include the plural forms as well. Unless otherwise defined, the ranges defined herein is intended to include values within the range as individually applied and may be considered to be the same as individual values constituting the range in the detailed description. Finally, operations constituting methods may be performed in appropriate order unless explicitly described in terms of order or described to the contrary. Exemplary embodiments are not necessarily limited to the order of operations given in the description. The examples or exemplary terms used herein are to merely describe exemplary embodiments in detail are not intended to limit the embodiments unless defined by the following claims. Also, those of ordinary skill in the art will readily appreciate that many alternations, combinations and modifications, may be made according to design conditions and factors within the scope of the appended claims and their equivalents.

It will be understood that when a unit, region, or component is referred to as being “formed on” another layer, region, or component, it can be directly on the other layer, region, or component or an intervening layer, region, or component may be present therebetween.

It will be understood that when an element is referred to as being “connected” or “coupled” to another element, it can be directly connected or coupled to the other element or intervening elements may be present.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

Embodiments of the present invention relate to a mask frame assembly manufacturing apparatus and a mask frame assembly manufacturing method designed to increase the precision and quality of mask frame assemblies used in display manufacturing, particularly for organic light-emitting displays (OLEDs). The apparatus includes a mask stage where a mask frame is positioned, an air injection module that injects air through multiple air holes to lift the mask frame, and a lifting module that ascends or descends to control the separation distance between the mask stage and the mask frame. This system may help in reducing friction between the mask frame and the mask stage, preventing misalignment and deformation during the welding of mask sheets to the mask frame.

The mask frame assembly is used to deposit materials onto substrates with high precision, which is desirable in display technology. According to embodiments of the present invention, the mask frame may remain properly tensioned and aligned when welding multiple mask sheets thereto. The air injection module lifts edge portions of the mask frame, while the lifting module supports and elevates specific points symmetrically to maintain even separation. This configuration may prevent unwanted deformation due to the recovery forces generated when welding the mask sheets, leading to a more consistent and defect-free manufacturing process.

According to embodiments of the present invention, separation distances may be dynamically adjusted based on different welding stages, ensuring that each mask sheet may be applied with uniform tension. The system may control the lifting heights of different portions of the mask frame, thereby maintaining its structural integrity and preventing sagging. The use of precisely positioned air holes and lifting modules may enable easier handling of the mask frame during manufacturing, resulting in higher accuracy in depositing materials onto substrates.

According to embodiments of the present invention, manufacturing efficiency of mask frame assemblies may be increased and defects may be reduced. In addition, by controlling the separation between the mask frame and the mask stage, the apparatus may minimize mechanical stress and increase the precision of the deposition process.

The embodiments of the present invention will be described below in more detail with reference to the accompanying drawings.

Hereinafter, a first direction and a second direction intersecting the first direction are defined as substantially horizontal directions, and a third direction is defined as a vertical direction. Also, in the embodiment of the present disclosure, the first direction may correspond to a lengthwise direction of a mask stage, the second direction may correspond to a width direction of the mask stage, and the third direction may correspond to a thickness direction of the mask stage.

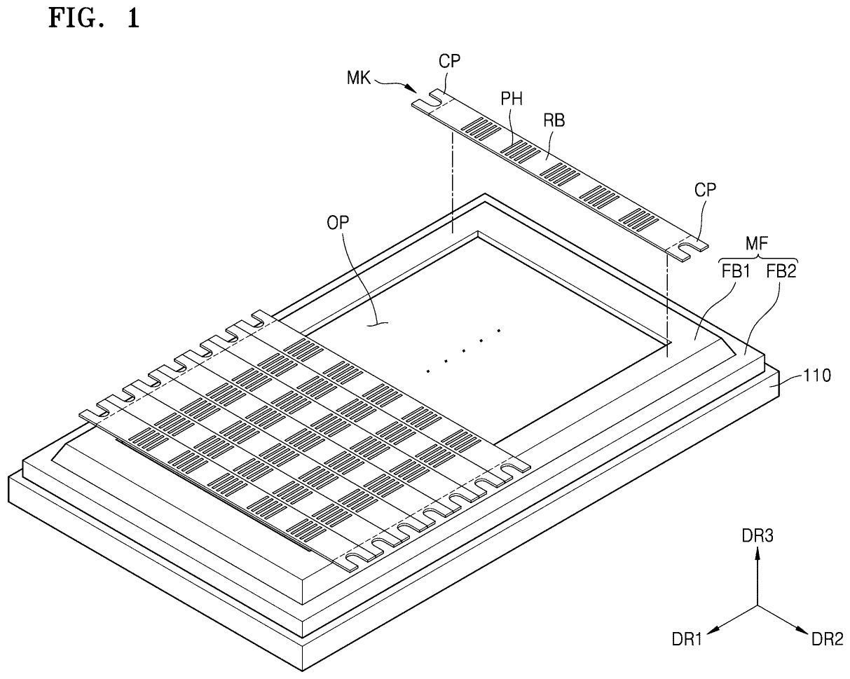

FIG. 1 is a perspective view of a mask frame MF and mask sheets MK according to an embodiment of the present invention.

Referring to FIG. 1, a plurality of mask sheets MK may be disposed on the mask frame MF. On a mask stage 110, the mask frame MF and the mask sheets MK are coupled to each other to form a mask frame assembly.

The mask frame MF may serve as a structural support for the mask sheets MK. The mask frame MF may have an opening OP. The mask sheets MK may be coupled onto the mask frame MF, and at this time, the mask sheets MK may cover the opening OP of the mask frame MF. The mask sheets MK may include pattern holes PH, which define the precise regions where deposition material will pass through. During a deposition process, a substrate is positioned beneath the mask frame assembly to overlap with the opening OP of the mask frame MF. As deposition material that is described later is applied, it first passes through pattern holes PH of the mask sheets MK, then through the opening OP of the mask frame MF, before being deposited onto the substrate in a controlled pattern.

In an embodiment of the present invention, the mask sheets MK may be tension-welded to the mask frame MF. The mask sheets MK may be tensioned welded to the mask frame MF while in a stretched state, ensuring secure attachment. The welding process can be performed by using various techniques, such as a laser welding, gas welding, etc.

In an embodiment of the present invention, the mask frame MF may include a first frame body FB1 and a second frame body FB2. The mask sheets MK may be welded to the first frame body FB1, and the second frame body FB2 may support the first frame body FB1. For example, the first frame body FB1 may be disposed on the second frame body FB2 and provide a region to which the mask sheets MK are welded to.

The first frame body FB1 and the second frame body FB2 may be integrally formed with each other or may be provided as different members to be coupled to each other.

For example, the first frame body FB1 and the second frame body FB2 may be each formed with a square frame shape having the opening OP in the center thereof.

For example, the first frame body FB1 and the second frame body FB2 may be each provided as a flat plate having a certain area and height, and may have the opening OP in the center thereof. Here, the area of the first frame body FB1 may be less than that of the second frame body FB2. In other words, the area of the region of the second frame body FB2, on which the first frame body FB1 is disposed, may be less than that of a region of the mask stage 110, on which the second frame body FB2 is disposed. As such, the first frame body FB1 may be stably disposed on the second frame body FB2, and the mask frame MF may have light weight.

The mask frame MF may have a metal material. The mask frame MF may be formed of a material that is less deformed when welding the mask sheets MK.

The mask sheets MK may be installed on the mask frame MF. The mask sheets MK are coupled to the first frame body FB1 and may cover the opening OP. Here, a plurality of mask sheets MK are provided and arranged continuously along a first direction DR1, to prevent sagging caused by their own weight.

In an embodiment of the present invention, the mask sheets MK may be each formed in a stick shape extending in a second direction DR2. For example, each of the mask sheets MK have a long, narrow, rectangular form. Here, the mask sheets MK may each include a plurality of pattern holes PH and rib portions RB connecting the pattern holes PH. The deposition material may be deposited on the substrate after passing through the pattern holes PH of the mask sheets MK. In addition, the number, arrangement positions, and shapes of the pattern holes PH shown in the drawings are examples, and according to an embodiment of the present invention, the pattern holes PH may be provided with a masking pattern maintaining a fully opened state or a mask pattern of a stripe shape.

The mask sheets MK may each have clamping portions CP provided for the tension-welding. The clamping portions CP may be removed after the mask sheets MK are tension-welded to the mask frame MF.

The mask sheets MK may be thin films having magnetic property and may be formed of various materials. For example, the mask sheet MK may include stainless steel, invar, nickel (Ni), cobalt (Co), nickel alloy, etc. In addition, the mask sheets MK may be formed of a nickel-cobalt alloy that is easy to form fine patterns and has excellent surface roughness.

In an embodiment of the present invention, the mask sheets MK may be manufactured by an etching method. For example, the mask sheet MK may be manufactured by forming a photoresist layer, which has the same pattern as the pattern holes PH, on a thin film by using a photoresist, or attaching a film having the pattern of the pattern holes PH on the thin film and then etching the thin film. In addition, the mask sheet MK may be manufactured by an electro-forming method or an electroless plating method.

A detailed method of manufacturing a mask frame assembly by tension-welding the mask sheets MK to the mask frame MF is described in detail below.

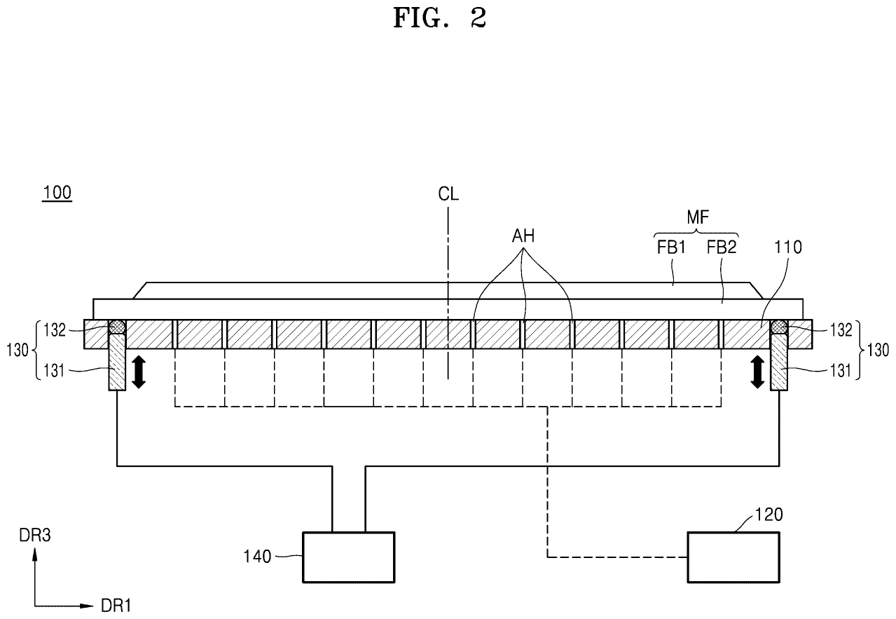

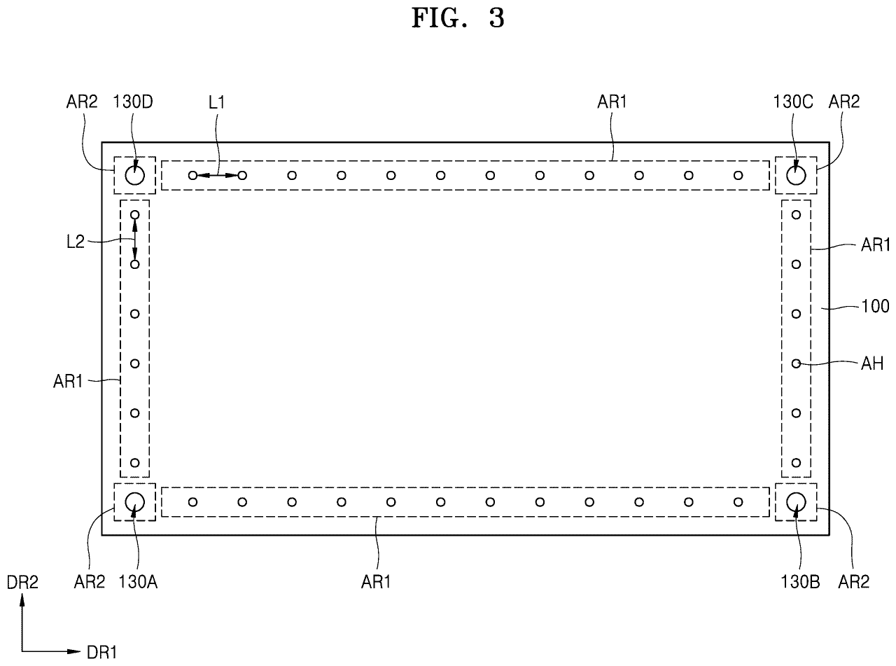

FIG. 2 is a side view schematically showing a mask frame assembly manufacturing apparatus 100 according to an embodiment of the present invention, and FIG. 3 is a plan view of the mask stage 110 of FIG. 2.

Referring to FIGS. 2 and 3, the mask frame assembly manufacturing apparatus 100 may include the mask stage 110, an air injection module 120 (e.g., an air injector), and a lifting module 130.

The mask stage 110 may support the mask frame MF. For example, the mask stage 110 may have a roughly rectangular flat plate shape, and the mask frame MF may be disposed on the flat plate. The mask sheets MK may be welded to the mask frame MF that is disposed on the mask stage 110. For example, the mask stage 110 may provide a space in which the mask frame assembly is manufactured.

The mask stage 110 may have a plurality of air holes AH. The air holes AH are formed to pass through the mask stage 110 and may provide a passage through which the air may flow. The air injection module 120 may inject air through the air holes AH that are formed in the mask stage 110.

The air holes AH may be disposed to correspond to the position of the mask frame MF that is disposed on the mask stage 110. For example, the mask frame MF may overlap the air holes AH. While the mask frame MF is disposed on the mask stage 110, the air holes AH may be located under the mask frame MF. Therefore, the air injected from the air injection module 120 through the air holes AH may lift the mask frame MF by a certain distance.

The air holes AH may be disposed in edge portions AR1 of the mask stage 110. For example, the edge portions AR1 may be adjacent to the edges of the mask stage 110. The air holes AH are disposed corresponding to the position where the mask frame MF is disposed and may be arranged in the edge portions AR1 of the mask stage 110. For example, as shown in FIG. 3, the plurality of air holes AH may be arranged in a substantially square shape along the edge portions of the mask stage 110.

In an embodiment of the present invention, an interval between the air holes AH may be variously set in consideration of a target separation distance and a target separation region of the mask frame MF that needs to be lifted. For example, this may allow for precise control over how the mask frame MF is elevated, ensuring substantially uniform tension and avoiding deformation in different regions of the mask frame MF.

For example, the plurality of air holes AH may be arranged densely to increase the separation distance between the mask stage 110 and the mask frame MF or to lift the entire region of the mask frame MF. For example, this arrangement may help ensure an even lift across the mask frame MF, preventing any uneven tension or sagging during the manufacturing process. In addition, the air holes AH may be arranged with large intervals therebetween to lift a partial region of the mask frame MF.

For example, the air holes AH may be arranged at a first interval L1 in the first direction DR1, and at a second interval L2 in the second direction DR2.

In an embodiment of the present invention, the first interval L1 and the second interval L2 may be equal to each other.

In an embodiment of the present invention, the first interval L1 and the second interval L2 may be different from each other. For example, the first interval L1 may be set to be less than the second interval L2, so that the air injection module 120 provides a greater lifting force in regions extending along the first direction DR1 to prevent the mask frame MF from sagging.

In an embodiment of the present invention, the intervals among the plurality of air holes AH arranged in the first direction DR1 may be different from each other. For example, the first interval L1 between the air holes AH arranged in the first direction DR1 may gradually increase from the center of the mask stage 110 toward both ends. As such, the air injection module 120 may provide greater lifting force at the center of the mask stage 110 and the sagging of the mask frame MF at the center of the mask stage 110 may be prevented.

In an embodiment of the present invention, the intervals among the plurality of air holes AH arranged in the second direction DR2 may be different from each other. For example, the second interval L2 between the air holes AH arranged in the second direction DR2 may gradually increase from the center of the mask stage 110 toward the both ends. As such, the air injection module 120 may provide greater lifting force at the center of the mask stage 110 and the sagging of the mask frame MF at the center of the mask stage 110 may be prevented.

In an embodiment of the present invention, a cross-sectional area of the air hole AH may be variously set in consideration of a target separation distance and a target separation region of the mask frame MF. Here, the air hole AH may have a circular cross-section, or may have various cross-sectional shapes such as a square shape, a triangular shape, etc.

When the air injection module 120 injects the same amount of air, a pressure of the injected air may vary depending on the cross-sectional area of the air hole AH. Therefore, the mask frame assembly manufacturing apparatus 100 may have the air holes AH having large cross-sectional areas, to adjust the separation distance of the mask frame MF to be reduced. In addition, the mask frame assembly manufacturing apparatus 100 may have the air holes AH having small cross-sectional aeras, to adjust the separation distance of the mask frame MF to be increased.

For example, the plurality of air holes AH may have the same cross-sectional areas as one another. In addition, the cross-sectional areas of the plurality of air holes AH may be set to be different from each other according to their respective positions. As described above, the cross-sectional areas of the plurality of air holes AH may be variously selected according to the target separation distance.

In an embodiment of the present invention, the mask stage 110 may be further provided with an air pocket having the air hole AH. When the air is injected through the air holes AH while the air is filled in the air pocket, the mask frame MF may be provided with even lifting force at the region corresponding to the air pocket. As such, the welding process may be performed stably while the position of the mask frame MF is aligned. For example, the mask frame MF may be aligned with the mask stage 110 or other reference points.

The air injection module 120 may inject the air toward the mask frame MF through the air holes AH. The air injection module 120 may separate the mask frame MF from the mask stage 110 due to the pressure of the injected air.

The air injection module 120 may separate edge portions of the mask frame MF from the mask stage 110. The air holes AH are disposed in the edge portions AR1 of the mask stage 110 to correspond to the position where the mask frame MF is disposed. Therefore, the air injected through the air holes AH may apply the pressure to the edge portions of the mask frame MF, and accordingly, the edge portions of the mask frame MF are lifted and separated from the mask stage 110.

The air injection module 120 may have various structures capable of supplying the air. For example, the air injection module 120 may include a pump, a nozzle, a flowmeter, a sensor, etc. For example, the air injection module 120 may have all components and devices that are necessary for injecting the air of a certain pressure through the air holes AH.

The air injection module 120 may adjust the pressure of the injected air in consideration of the target separation distance and the target separation region of the mask frame MF. When the separation distance is large or the target separation region is wide, the air injection module 120 may inject the air with high pressure. In addition, the air injection module 120 may inject the air while varying the pressure of the plurality of air holes AH depending on the target separation distance and the target separation region of the mask frame MF.

The lifting module 130 may move up and down in the height direction (e.g., the third direction DR3) of the mask stage 110. The lifting module 130 may separate the mask frame MF from the mask stage 110 while moving in the third direction DR3.

The lifting module 130 may support the mask frame MF through the mask stage 110. The lifting module 130 may lift the mask frame MF while ascending or descending through the mask stage 110. For example, the lifting module 130 may move through the mask stage 110.

For example, the lifting module 130 may include a lifting body 131 and a contact portion 132.

The lifting body 131 may be partially disposed in a hole formed in the mask stage 110. The lifting body 131 may ascend or descend in the hole along the height direction of the mask stage 110.

In an embodiment of the present invention, the lifting body 131 is connected to a driving motor and receives the driving power to ascend or descend. In an embodiment of the present invention, the lifting body 131 may be formed in a piston-cylinder structure. That is, the way of ascending and descending the lifting body 131 is not particularly restricted.

The contact portion 132 is coupled to the lifting body 131 and may come into contact with the mask frame MF. As the lifting body 131 ascends or descends, the contact portion 132 may also ascend or descend along with the lifting body 131. For example, the contact portion 132 may lift the mask frame MF while moving up along with the lifting body 131.

In an embodiment of the present invention, the contact portion 132 may be rotatably coupled to the lifting body 131. For example, the contact portion 132 may be a bearing of various kinds and specifications, e.g., a ball bearing, etc. As the contact portion 132 rotates while coming into contact with the mask frame MF when the lifting body 131 moves up, the friction between the contact portion 132 and the mask frame MF may be reduced. As a result, the damage to the mask frame MF may be prevented when the lifting module 130 lifts the mask frame MF.

The lifting module 130 may separate corner portions of the mask frame MF from the mask stage 110. The lifting module 130 may be placed at each corner portion AR2 of the mask stage 110 to correspond to the position where the mask frame MF is disposed. As a result, the lifting module 130 may lift the corner portions of the mask frame MF while ascending and descending.

A plurality of lifting modules 130 may be provided. The plurality of lifting modules 130 may respectively support the mask frame MF. Here, a plurality of points of the mask frame MF, which are respectively supported by the plurality of lifting modules 130, may be symmetrical to each other relative to a virtual reference line CL passing the center of the mask stage 110. That is, the plurality of lifting modules 130 may lift the mask frame MF by supporting the plurality of points that are symmetrical to each other on the mask frame MF.

In an embodiment of the present invention, the mask frame assembly manufacturing apparatus 100 may further include an auxiliary module. The auxiliary module is disposed between the plurality of lifting modules 130 and may lift the mask frame MF while supporting the mask frame MF along with the lifting modules 130. For example, the lifting modules 130 may lift the mask frame MF while supporting the corner portions AR2 of the mask frame MF, and the auxiliary module may lift the mask frame MF while supporting the edge portion AR1 of the mask frame MF. As such, the mask frame assembly manufacturing apparatus 100 may evenly lift the entire region of the mask frame MF.

Hereinafter, for the convenience of description, an embodiment in which the mask frame assembly manufacturing apparatus 100 includes four lifting modules 130 as shown in FIG. 3 and the lifting modules 130 are respectively disposed at four corners of the mask stage 110, is described below; however, the present invention is not limited thereto. In FIG. 3, the lifting modules 130 arranged at a left lower end, a right lower end, a left upper end, and a right upper end are respectively defined as a first lifting module 130A, a second lifting module 130B, a third lifting module 130C, and a fourth lifting module 130D.

The mask frame assembly manufacturing apparatus 100 may further include a driver 140.

The driver 140 may be connected to the lifting modules 130 to provide the driving force. For example, the driver 140 may include a driving motor to provide the lifting modules 130 with the driving force. Here, one driving motor may be connected to all of the first lifting module 130A to the fourth lifting module 130D, to provide the first to fourth lifting modules 130A to 130D with the driving force simultaneously or sequentially. In addition, four driving motors may be respectively connected to the first to fourth lifting modules 130A to 130D to provide the first to fourth lifting modules 130A to 130D with the driving force simultaneously or sequentially.

The driver 140 supplies the driving force to the first to fourth lifting modules 130A to 130D, causing the plurality of points on the mask frame MF, which are respectively supported by the lifting modules 130, to be separated from the mask stage 110 by a preset distance. Here, the driver 140 may control the first to fourth lifting modules 130A to 130D so that the elevation heights of the first to fourth lifting modules 130A to 130D are equal to each other, or may control the first to fourth lifting modules 130A to 130D to have different elevation heights from each other.

Next, a method of manufacturing the mask frame assembly by using the mask frame assembly manufacturing apparatus 100 is described below in detail. Hereinafter, the plurality of mask sheets MK are defined as a first mask sheet MK1, a second mask sheet MK2, . . . , an n-th mask sheet MKn, according to an order of being welded to the mask frame MF.

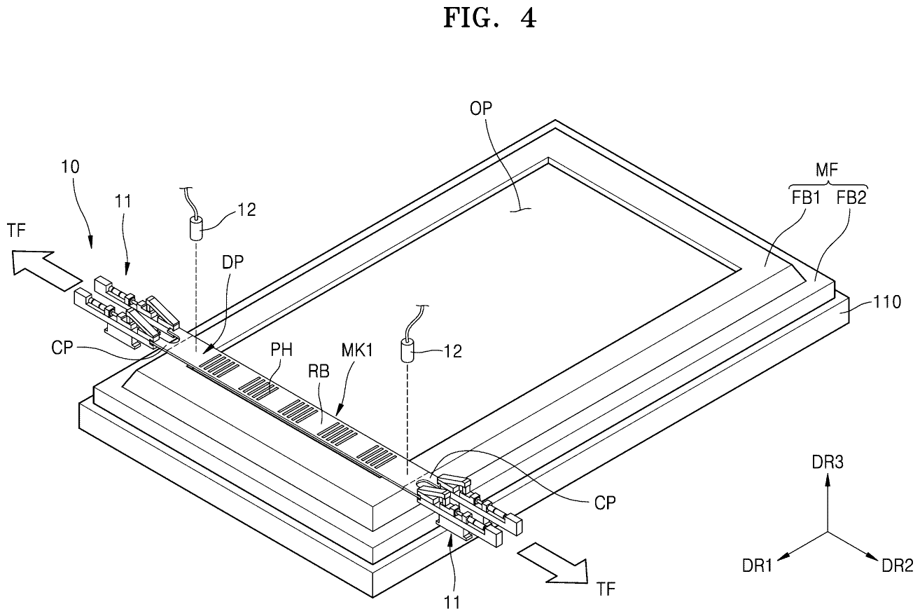

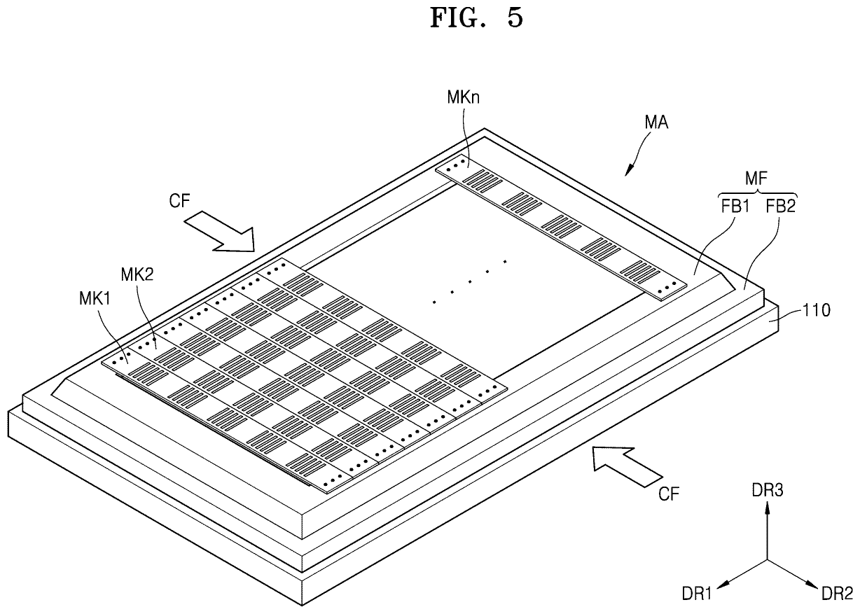

FIGS. 4 and 5 are perspective views schematically illustrating processes of manufacturing a mask frame assembly of FIG. 1.

Referring to FIGS. 4 and 5, the mask sheets MK may be welded to the mask frame MF to manufacture a mask frame assembly MA. When the mask sheet MK is disposed on the mask frame MF, a mask tension-welding apparatus 10 may weld the mask sheet MK to the mask frame MF while stretching the mask sheet MK.

The mask tension-welding apparatus 10 may include a stretching portion 11, a pressing portion, and a welding portion 12.

The stretching portion 11 may stretch the mask sheet MK in the lengthwise direction. The mask sheet MK is stretched by the stretching portion 11 so that the clamping portions CP may be located above the mask frame MF.

The stretching portion 11 may stretch the mask sheet MK in the lengthwise direction and fix the mask sheet MK onto the mask frame MF. Here, a certain tensile force TF may be applied to the clamping portion CP of the mask sheet MK that is stretched by the stretching portion 11, to prevent sagging due to the weight of the mask sheet MK itself. When the mask sheet MK is welded to the mask frame MF while the tensile force TF is applied thereto, the mask frame assembly MA may be manufactured without deforming the mask sheet MK. Consequently, the deposition material deposited on the substrate may be effectively deposited on a target region after passing through the mask sheet MK.

In an embodiment of the present invention, the stretching portion 11 may be a mask stretching clamp. For example, the stretching portion 11 may stretch the mask sheet MK by clamping the clamping portion CP of the mask sheet MK.

The pressing portion may allow the mask sheet MK to be in close contact with the mask frame MF. The pressing portion may apply a pressure onto the mask sheet MK located on the mask frame MF, and as such, facing surfaces of the mask sheet MK and the mask frame MF may be in close contact with each other.

The pressing portion may be installed on a location that is adjacent to each of the clamping portions CP at both ends of the mask sheet MK. For example, as shown in FIG. 4, the pressing portion may be disposed between an outermost pattern hole DP and the clamping portion CP of the mask sheet MK.

The welding portion 12 may weld the mask sheet MK to the mask frame MF. Here, the mask sheet MK may be maintained in a tensile state. The welding portion 12 may weld the mask sheet MK by using various methods such as a laser welding, a gas welding, etc. The method of welding the mask sheet MK with the welding portion 12 is not particularly restricted, and may be selected according to the material that is included in the mask sheet MK, etc.

Hereinafter, an embodiment of the present invention in which the welding portion 12 performs the welding by emitting a laser beam onto the mask sheet MK is described below.

The welding portion 12 may emit the laser beam onto one or more points of the mask sheet MK. The welding portion 12 emits the laser beam onto one surface of the mask sheet MK, which is located in an inward direction or outward direction based on the contacting surfaces of the pressing portion and the clamping portion CP of the mask sheet MK, to weld the mask sheet MK to the mask frame MF. Due to the laser beam being emitted from the welding portion 12, parts of the mask frame MF and the mask sheet MK are melted along with each other to be connected to each other.

FIG. 4 shows a process in which the mask tension-welding apparatus 10 tension-welds the first mask sheet MK1. The first mask sheet MK1 may be welded to the mask frame MF in a tensile state. Here, the tensile force TF may be applied to the first mask sheet MK1 due to the mask tension-welding apparatus 10.

After the first mask sheet MK1 and the mask frame MF are coupled to each other, a recovery force CF may be applied to the first mask sheet MK1 in a direction opposite to the direction in which the tensile force TF applies. The tensile force TF applied to the mask sheet MK for tension-welding of the first mask sheet MK1 may result in the recovery force CF, which acts to return the first mask sheet MK1 to its original state after the welding. The recovery force CF may affect the shape of the mask frame MF to which the first mask sheet MK1 is welded, as well as the first mask sheet MK1. FIG. 5 shows a state in which the recovery force CF applies while n mask sheets MK are welded to the mask frame MF.

In addition, the recovery force CF may be offset by the recovery force CF that generates according to the tensile force TF that is applied to the second mask sheet MK2 that is to be welded next. The offset of the recovery force CF may be affected by variables such as a manufacturing process distribution, a material property distribution, a welding state, etc. of the mask sheet MK. For example, the recovery force CF might not be offset due to the frictional force between the mask stage 110 and the mask frame MF, and the mask frame MF and the mask sheet MK may be deformed.

Therefore, the mask frame assembly manufacturing apparatus 100 separates the mask frame MF from the mask stage 110 by a certain distance by using at least one of the air injection module 120 or the lifting module 130 when each of the mask sheets MK is welded, and thus, the frictional force between the mask frame MF and the mask stage 110 may be reduced.

The mask frame assembly manufacturing apparatus 100 reduces the contact area between the mask stage 110 and the mask frame MF, and thus, may remove the friction force between the mask stage 110 and the mask frame MF, and moreover, may precisely control the tensile force TF and the recovery force CF that are applied to the mask frame MF and the mask sheet MK.

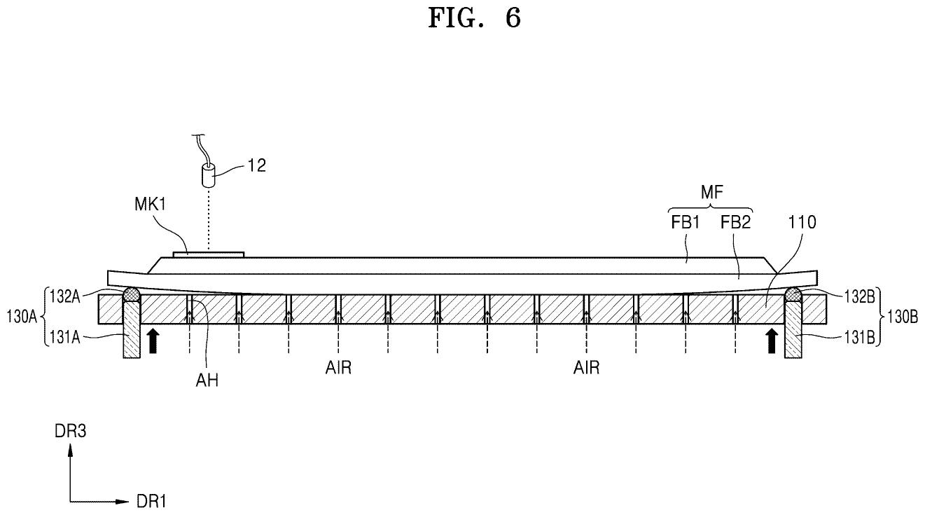

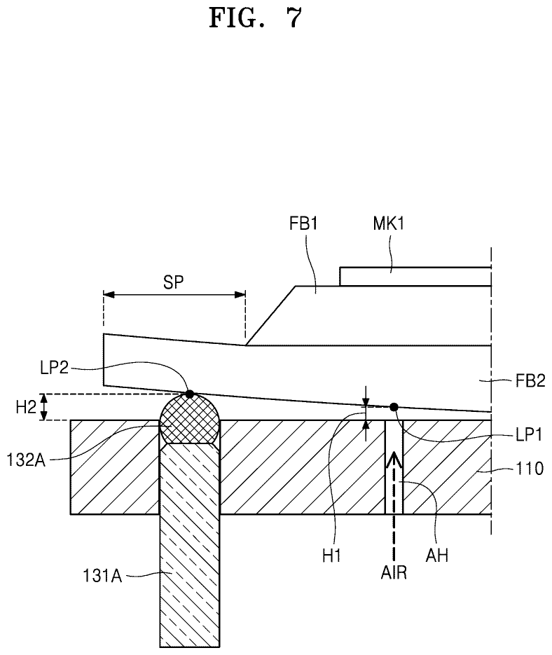

FIG. 6 is a diagram conceptually showing a process in which the first mask sheet MK1 is welded to the mask frame MF of FIG. 2, and FIG. 7 is an enlarged view of a region in FIG. 6.

Referring to FIGS. 6 and 7, the mask frame MF may be lifted to be separated from the mask stage 110 by a preset distance when the first mask sheet MK1 is welded to the mask frame MF.

For example, the air injection module 120 may generate an upward force by injecting pressurized air through the air holes AH to lift the edge portions AR1 of the mask frame MF, and the lifting module 130 may lift the corner portions AR2 of the mask frame MF by moving up while supporting the mask frame MF.

When a point of the mask frame MF, which is lifted by the pressurized air that is generated by the air injection module 120, is defined as a first point LP1, the first point LP1 may be separated by a first height H1 from the mask stage 110. Likewise, when a point of the mask frame MF, which is lifted by the lifting module 130, is defined as a second point LP2, the second point LP2 may be separated by a second height H2 from the mask stage 110.

In an embodiment of the present invention, the second point LP2 may be located in a peripheral region SP of the second frame body FB2, where the first frame body FB1 is not disposed. That is, the lifting module 130 may effectively lift the mask frame MF by pushing up the peripheral region SP of the second frame body FB2.

In an embodiment of the present invention, the first height H1 may be equal to the second height H2. The edge portions and the corner portions of the mask frame MF may be lifted to the same height due to the air injection module 120 and the lifting module 130.

In an embodiment of the present invention, the first height H1 may be different from the second height H2. For example, the first height H1 may be less than the second height H2. For example, the separation distance between the mask stage 110 and the mask frame MF due to the lifting module 130 may be greater than the separation distance of between the mask stage 110 and the mask frame MF due to the air injection module 120. Because the corner portion AR2 is lifted more than the edge portion AR1 of the mask frame MF, the mask sheet MK may be tension-welded while stably disposed on the mask frame MF.

In addition, because the lifting module 130 may relatively further lift the second point LP2 at the corner portion AR2 of the mask frame MF when compared to the first point LP1, the center region of the mask frame MF may be sagged downward. The sagging of the mask frame MF may be determined according to a first interval and a second interval. The mask frame assembly manufacturing apparatus 100 may control the frictional force between the mask frame MF and the mask stage 110 to be within a reference range by lifting the mask frame MF after precisely predicting the deformation and position of the mask frame MF.

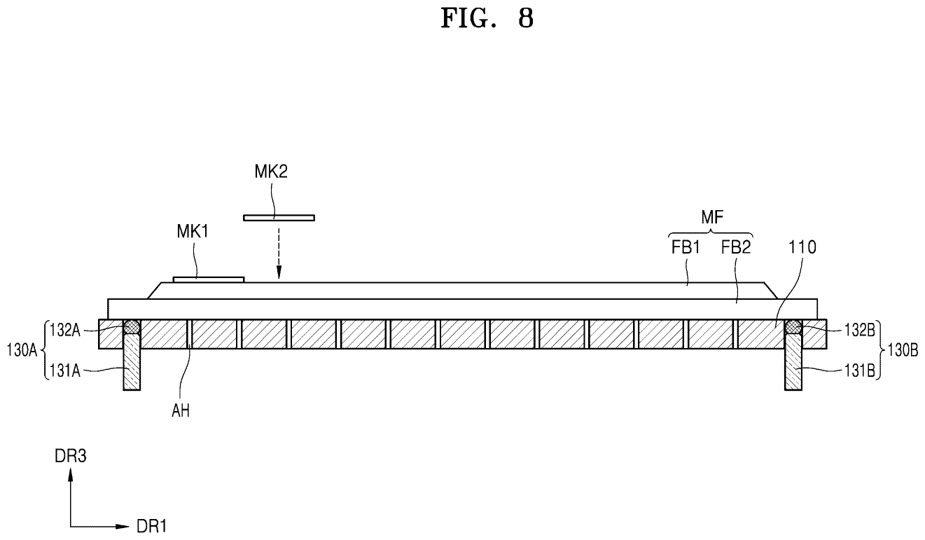

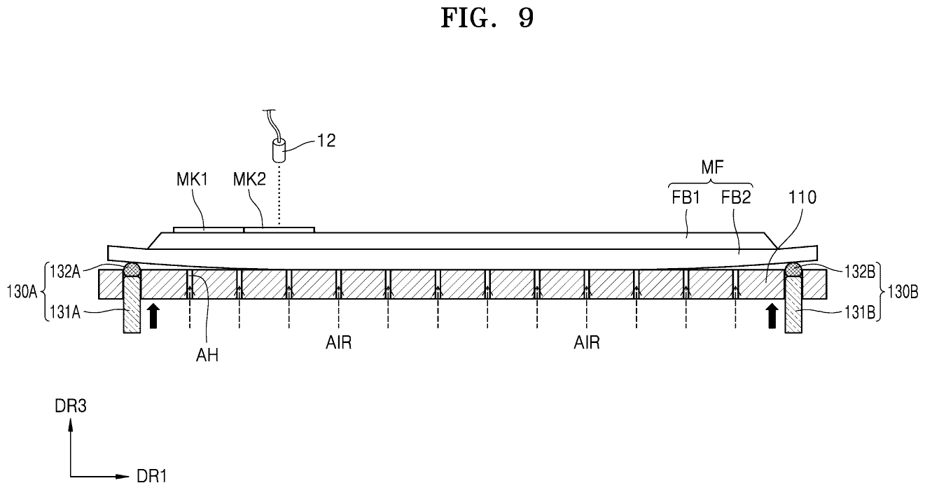

FIGS. 8 and 9 are diagrams conceptually showing a process of welding the second mask sheet MK2 to the mask frame MF of FIG. 1.

Referring to FIGS. 8 and 9, after the first mask sheet MK1 is welded to the mask frame MF, the second mask sheet MK2 may be welded. When the second mask sheet MK2 is welded, the mask frame MF may be separated from the mask stage 110.

For example, when the first mask sheet MK1 is welded to the mask frame MF, the mask frame MF may come into contact with the mask stage 110 again and then may be supported as shown in FIG. 8. In this state, the second mask sheet MK2 is carried onto the mask frame MF, and then, the mask tension-welding apparatus 10 may tension-weld the second mask sheet MK2 to the mask frame MF.

Like the first mask sheet MK1, when the second mask sheet MK2 is welded, at least one of the air injection module 120 or the lifting module 130 may lift the mask frame MF to separate the mask frame MF from the mask stage 110. FIG. 9 is a diagram showing a state of lifting the mask frame MF when the second mask sheet MK2 is welded.

The mask frame assembly manufacturing apparatus 100 may repeatedly perform the process of separating the mask frame MF from the mask stage 110 whenever each of the mask sheets MK is tension-welded. For example, the mask frame assembly manufacturing apparatus 100 may reduce the frictional force between the mask frame MF and the mask stage 110 during the welding of the mask sheets MK. As such, the mask frame assembly manufacturing apparatus 100 may regulate the tensile force and the recovery force applied to the mask sheets MK, as well as manage the deformation of both the mask sheets MK and the mask frame MF, ensuring they remain within a controlled and predetermined reference range.

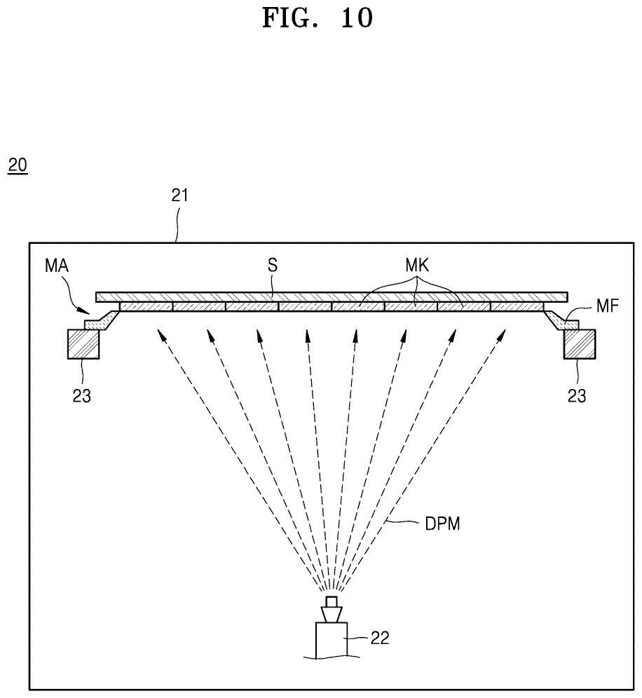

FIG. 10 is a diagram schematically showing a deposition process of a deposition layer on a substrate S by using the mask frame assembly of FIG. 1.

Referring to FIG. 10, a deposition apparatus 20 may include a vacuum chamber 21 to deposit an organic emission layer of an organic light-emitting display apparatus or an electrode by using the mask frame assembly MA.

A deposition source 22 is disposed in the vacuum chamber 21, and the mask frame assembly MA may be installed above the deposition source 22. Here, the mask frame assembly MA may include a plurality of mask sheets MK. The mask sheets MK may be disposed on the mask frame MF, and the substrate S may be disposed on the mask sheets MK. In addition, additional support members 23 may be provided at the edges of the mask frame assembly MA for fixing the mask frame assembly MA.

Processes of depositing a deposition material DPM on the substrate S are described briefly as follows.

First, the mask frame assembly MA is fixed onto the support members 23, and the substrate S for deposition may be located on the mask sheets MK. Next, the deposition material DPM may be sprayed toward the mask frame assembly MA from the deposition source 22 that is located in the vacuum chamber 21. The deposition material DPM that has passed through the mask sheets MK may be deposited on one surface of the substrate S. The deposition material DPM deposited on the substrate S may have a certain pattern due to the pattern holes PH that are in the mask sheets MK.

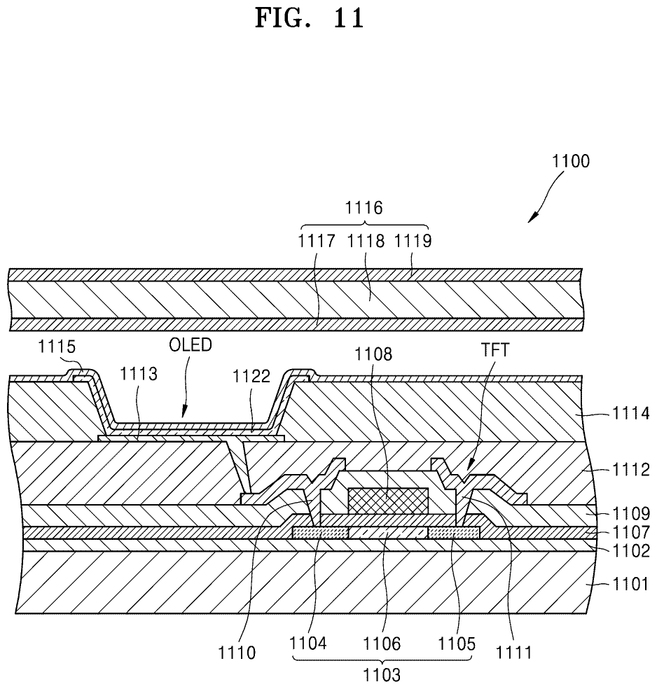

FIG. 11 is a cross-sectional view of a sub-pixel in an organic light-emitting display apparatus in which an emission layer is deposited on the substrate S of FIG. 10.

Referring to FIG. 11, the organic light-emitting display apparatus may include a display substrate 1101. The display substrate 1101 may be formed of an insulating material that is flexible, or an insulating material that is rigid. The display substrate 1101 may be transparent, translucent, or opaque.

A barrier layer 1102 may be formed on the display substrate 1101. The barrier layer 1102 may cover the upper surface of the display substrate 1101. For example, the barrier layer 1102 may entirely cover the upper surface of the display substrate 1101. The barrier layer 1102 may include an inorganic layer and/or an organic layer.

A thin film transistor TFT may be formed on the barrier layer 1102. A semiconductor active layer 1103 may be formed on the barrier layer 1102. The semiconductor active layer 1103 may include a source region 1104 and a drain region 1105, which may be formed by doping with N-type impurity ions or P-type impurity ions. A region of the semiconductor active layer 1103 that is between the source region 1104 and the drain region 1105 may be a channel region 1106 that is not doped with impurities.

A gate insulating layer 1107 may be formed on the semiconductor active layer 1103. The gate insulating layer 1107 may include an inorganic layer such as silicon oxide, silicon nitride, or a metal oxide. The gate insulating layer 1107 may have a single-layered or multi-layered structure.

A gate electrode 1108 may be formed on a certain region of the gate insulating layer 1107. For example, the gate electrode 1108 may overlap the channel region 1106. For example, the gate electrode 1108 may include a single-layered or multi-layered film including Au, Ag, Cu, Ni, Pt, Pd, Al, Mo, Cr, etc. The gate electrode 1108 may include an alloy such as Al:Nd and Mo:W.

An interlayer insulating layer 1109 may be formed on the gate electrode 1108. The interlayer insulating layer 1109 may include an inorganic layer such as silicon oxide, silicon nitride, etc., or an organic layer.

A source electrode 1110 and a drain electrode 1111 may be formed on the interlayer insulating layer 1109. For example, in the gate insulating layer 1107 and the interlayer insulating layer 1109, contact holes may be formed by selectively removing portions of the gate insulating layer 1107 and the interlayer insulating layer 1109. The source electrode 1110 may be electrically connected to the source region 1104 and the drain electrode 1111 may be electrically connected to the drain region 1105 via the contact holes penetrating the gate insulating layer 1107 and the interlayer insulating layer 1109.

A protective layer 1112 (e.g., passivation layer and/or planarization layer) may be formed on the source electrode 1110 and the drain electrode 1111. The protective layer 1112 may include an inorganic layer such as silicon oxide or silicon nitride, or an organic layer such as acryl, polyimide, benzocyclobutene (BCB), etc.

An organic light-emitting diode OLED may be formed above the thin film transistor TFT.

The organic light-emitting diode OLED may be formed on the protective layer 1112. The organic light-emitting diode OLED may include a first electrode 1113, an intermediate layer 1122 including an organic emission layer, and a second electrode 1115.

The first electrode 1113 functions as an anode and may include various conductive materials. The first electrode 1113 may be formed as a transparent electrode or a reflective electrode. For example, when the first electrode 1113 is used as the transparent electrode, the first electrode 1113 may include a transparent conductive layer. When the first electrode 1113 is used as a reflective electrode, the first electrode 1113 may include a reflective layer and a transparent conductive layer that is formed on the reflective layer.

A pixel defining layer 1114 may partially cover the protective layer 1112 and the first electrode 1113. For example, an opening in the pixel defining layer 1114 may overlap the first electrode 1113. The pixel defining layer 1114 may define an emission region in each sub-pixel by surrounding the edges of the first electrode 1113. The first electrode 1113 may be patterned in each sub-pixel. The pixel defining layer 1114 may include an organic layer or an inorganic layer. Additionally, the pixel defining layer 1114 may be formed as a single-layered or multi-layered film.

The intermediate layer 1122 may be formed on the first electrode 1113 in a region that is exposed through partially etching of the pixel defining layer 1114. The intermediate layer 1122 may be formed through a deposition process. The intermediate layer 1122 may be patterned by the deposition material that is deposited after passing through the pattern holes PH of the mask sheets MK in FIG. 1.

The intermediate layer 1122 may include the organic emission layer. In an example, the intermediate layer 1122 may include the organic emission layer, and may further include at least one of a hole injection layer (HIL), a hole transport layer (HTL), an electron transport layer (ETL), and/or an electron injection layer (EIL). The embodiment of the present invention is not limited thereto. For example, the intermediate layer 1122 may include the organic emission layer and may further include other various functional layers.

The second electrode 1115 may be formed on the intermediate layer 1122.

The second electrode 1115 may function as a cathode. The second electrode 1115 may include a transparent electrode or a reflective electrode. For example, when the second electrode 1115 is used as the transparent electrode, the second electrode 1115 may include a metal layer, and a transparent conductive layer formed on the metal layer. When the second electrode 1115 is used as the reflective layer, the second electrode 1115 may include a metal layer.

In an embodiment of the present invention, a plurality of sub-pixels may be formed on the display substrate 1101, and each sub-pixel may implement red light, green light, blue light, or white light. However, the present invention is not limited thereto.

A sealing substrate 1116 may be formed above the organic light-emitting diode OLED. The sealing substrate 1116 may be formed to protect the intermediate layer 1122 and other thin films against the external environment, moisture, and/or oxygen. The sealing substrate 1116 may include a glass that is rigid, a polymer resin, or a film that is flexible. The sealing substrate 1116 may be formed by alternately laminating organic layers 1117 and 1119 and an inorganic layer 1118 on the organic light-emitting diode OLED. In an embodiment of the present invention, at least one of each of the organic layers 1117 and 1119 and the inorganic layer 1118 may be provided.

The display apparatus according to an embodiment of the present invention may be applied to various electronic devices 1000. An electronic device 1000 according to an embodiment of the present invention may include the display apparatus described above, and may further include a module or device having additional functions, in addition to the display apparatus.

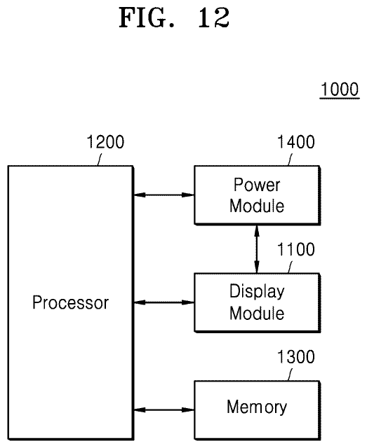

FIG. 12 is a block diagram of an electronic device according to an embodiment of the present invention. Referring to FIG. 12, an electronic device 1000 according to an embodiment of the present invention may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

The memory 1300 may store data information for operation of the processor 1200 or the display module 1100. An image data signal and/or an input control signal may be transmitted to the display module 1100 in a case where the processor 1200 executes an application that is stored in the memory 1300, and the display module 1100 may output image information through a display screen by processing the received signal.

The power module 1400 may include a power supply module, such as a power adapter or a battery device, and a power conversion module which converts power supplied by the power supply module to generate power for the operation of the electronic device 1000.

At least one of respective components of the electronic device 1000 may be included in the display apparatus according to embodiments of the present invention described above. In embodiments of the present invention, some of the individual modules functionally included in a module may be included in a display apparatus, while others may be provided separately from the display apparatus. For example, the display apparatus may include the display module 1100, and the processor 1200, the memory 1300, and the power module 1400 may be provided in the form of other apparatuses in the electronic device 1000 other than the display apparatus.

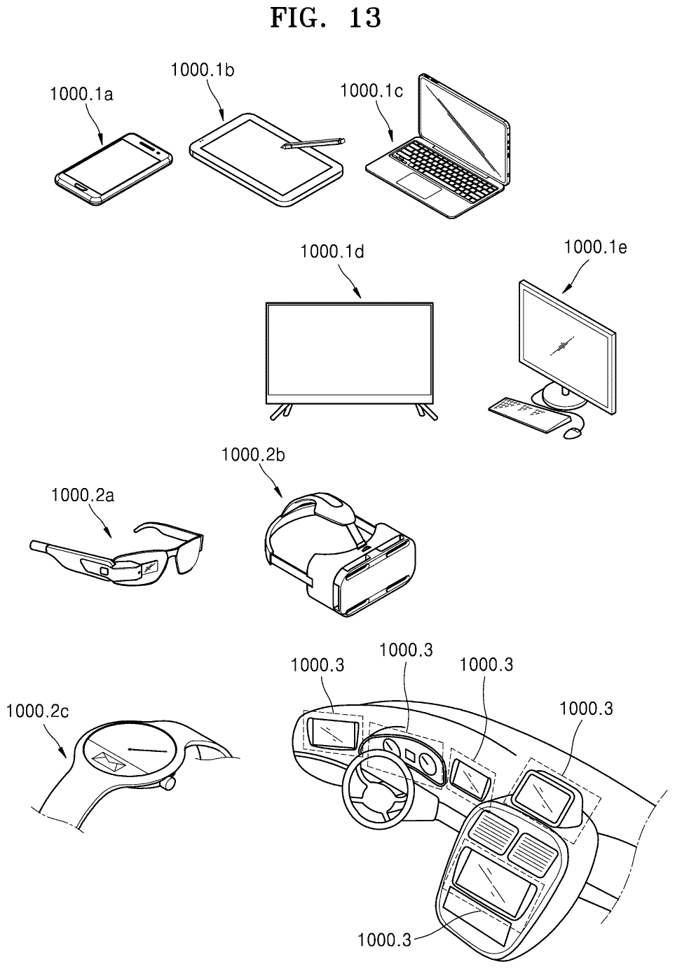

FIG. 13 illustrates schematic views of individual electronic devices according to various embodiments of the present invention.

Referring to FIG. 13, various electronic devices according to embodiments of the present invention, to which the display apparatus is applied, may include: an electronic device for displaying an image, such as a smart phone 1000.1a, a tablet PC 1000.1b, a laptop computer 1000.1c, a TV set 1000.1d, a desk monitor 1000.1e, and the like; a wearable electronic device including a display module, such as smart glasses 1000.2a, a head mounted display 1000.2b, a smart watch 1000.2c, and the like; and an electronic device 1000.3 for vehicles including a display module, such as a center information display (CID) arranged on an instrument panel, center fascia, or dashboard of a vehicle, a room mirror display, and the like.

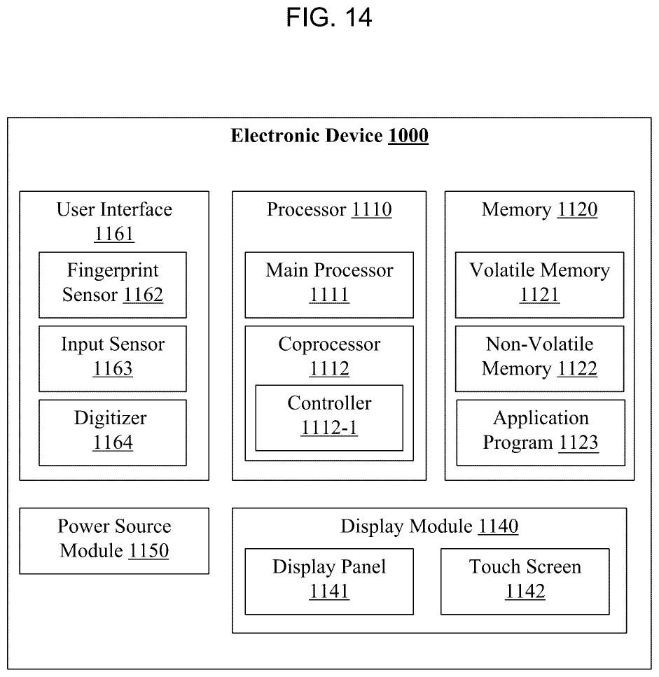

FIG. 14 is a diagram illustrating an electronic device according to an embodiment of the present invention. Referring to FIG. 14, the electronic device 1000 according to an embodiment of the present invention may output various information (e.g., images, text, music, etc.) through a display module 1140, which, for example, may correspond to the display apparatus. When a processor 1110 executes an application stored in a memory 1120, the display module 1140 may provide application information to a user through a display panel 1141.

In some embodiments of the present invention, the electronic device 1000 may be configured as a smartphone, camera, smart TV, monitor, smartwatch, tablet, automotive display, or AR/VR headset. For example, the electronic device 1000 may be a smartphone including a touch-sensitive display area (e.g., the display area DA) for interaction and a non-display area (e.g., non-display area NDA) including sensors and circuits for enhanced functionality. For example, the electronic device 1000 may be a television or monitor including a large display area DA for high-resolution video playback and a non-display area incorporating driving circuits or connectivity modules for external inputs. For example, the electronic device 1000 may be a smartwatch including a display area DA optimized for compact and high-clarity visuals and a non-display area integrating biometric sensors for health monitoring. In some cases, the electronic device 1000 be an AR/VR headset.

In some embodiments of the present invention, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display apparatus.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include a display unit.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

For example, the disclosure about the electronic device 1000 of FIG. 14 may be combinable with the disclosure about the electronic device 1000 of FIG. 12 and the electronic devices of FIG. 13.

According to the mask frame assembly manufacturing apparatus and the mask frame assembly manufacturing method using the same of an embodiment of the present invention, the mask frame may be separated from the mask stage by a certain distance when the mask sheet is welded to the mask frame.

According to the mask frame assembly manufacturing apparatus and the mask frame assembly manufacturing method using the same of an embodiment of the present invention, the air injection module may lift the mask frame by injecting the air toward the mask frame through the air holes, and the lifting module may lift the mask frame by moving up while supporting the mask frame.

As such, according to embodiments of the present inventive concept, the tensile force and the recovery force that are applied to the mask sheet and the deformation of the mask sheet and the mask frame may be controlled within a reference range, and the mask frame assembly of uniform quality may be precisely manufactured.

According to the mask frame assembly manufacturing apparatus and the mask frame assembly manufacturing method using the same of an embodiment of the present inventive concept, the mask frame assembly of high quality may be precisely manufactured by adjusting a separation distance between the mask stage and the mask frame.

Each of the embodiments described above may be implemented independently, but it is obvious that the structure of each embodiment may be applied in combination to other embodiments.

While the present invention has been described with reference to embodiments thereof, it will be understood by those of ordinary skill in the art that various changes in form and details may be made thereto without departing from the spirit and scope of the present invention.

What is claimed is:

1. A mask frame assembly manufacturing apparatus comprising:
a mask stage including a plurality of air holes, wherein a mask frame is disposed on the mask stage;
an air injection module injecting air toward the mask frame through the air holes; and
a lifting module that ascends or descends in a height direction of the mask stage to adjust a separation distance between the mask stage and the mask frame.

2. The mask frame assembly manufacturing apparatus of claim 1, wherein
the air injection module separates edge portions of the mask frame from the mask stage.

3. The mask frame assembly manufacturing apparatus of claim 1, wherein
the lifting module separates corner portions of the mask frame from the mask stage.

4. The mask frame assembly manufacturing apparatus of claim 1, wherein
the lifting module comprises:
a lifting body configured to move in the height direction of the mask stage and to extend through the mask stage; and
a contact portion that is rotatably coupled to the lifting body and comes into contact with the mask frame.

5. The mask frame assembly manufacturing apparatus of claim 1, wherein
the lifting module is of a plurality of lifting modules, wherein the plurality of lifting modules support a plurality of points, of the mask frame, that are symmetrical to each other with respect to a virtual reference line passing through a center of the mask frame.

6. The mask frame assembly manufacturing apparatus of claim 5, wherein
the plurality of lifting modules simultaneously separate the plurality of points of the mask frame from the mask stage by predetermined distances.

7. The mask frame assembly manufacturing apparatus of claim 5, further comprising:
a driver having a driving motor connected to the plurality of lifting modules and controlling the ascending and descending of the lifting modules.

8. The mask frame assembly manufacturing apparatus of claim 1, wherein
the plurality of the air holes are provided in the mask stage, and are arranged with first intervals along a lengthwise direction of the mask stage and with second intervals along a width direction of the mask stage.

9. The mask frame assembly manufacturing apparatus of claim 1, wherein
the air injection module lifts a plurality of first points of the mask frame by a first height, and
the lifting module lifts a plurality of second points of the mask frame by a second height.

10. The mask frame assembly manufacturing apparatus of claim 9, wherein
the first height is different from the second height.

11. The mask frame assembly manufacturing apparatus of claim 1, wherein
the mask frame comprises:
a first frame body to which a mask sheet is welded; and
a second frame body supporting the first frame body,
wherein the lifting module lifts a peripheral region of the second frame body, on which the first frame body is not disposed.

12. A mask frame assembly manufacturing method comprising:
disposing a mask frame on a mask stage; and
obtaining a mask frame assembly by welding a plurality of mask sheets to the mask frame,
wherein the obtaining of the mask frame assembly comprises:
adjusting a separation distance between the mask stage and the mask frame by using at least one of an air injection module or a lifting module; and
welding a first mask sheet of the plurality of mask sheets to the mask frame.

13. The mask frame assembly manufacturing method of claim 12, wherein
the adjusting of the separation distance comprises:
separating the mask frame from the mask stage by injecting air from the air injection module toward the mask frame; and
separating the mask frame from the mask stage by moving the lifting module in a height direction of the mask stage.

14. The mask frame assembly manufacturing method of claim 12, wherein
the air injection module separates edge portions of the mask frame from the mask stage.

15. The mask frame assembly manufacturing method of claim 12, wherein
the lifting module separates corner portions of the mask frame from the mask stage.

16. The mask frame assembly manufacturing method of claim 12, wherein
the lifting module comprises:
a lifting body configured to move in a height direction of the mask stage and to extend through the mask stage; and
a contact portion that is rotatably coupled to the lifting body and comes into contact with the mask frame.

17. The mask frame assembly manufacturing method of claim 12, wherein
the lifting module is of a plurality of the lifting modules, wherein the plurality of lifting modules support a plurality of points, of the mask frame, that are symmetrical to each other with respect to a virtual reference line passing through a center of the mask frame.

18. The mask frame assembly manufacturing method of claim 12, wherein
the air injection module lifts a plurality of first points of the mask frame by a first height, and
the lifting module lifts a plurality of second points of the mask frame by a second height.

19. The mask frame assembly manufacturing method of claim 18, wherein the first height is different from the second height.

20. The mask frame assembly manufacturing method of claim 12, wherein
the obtaining of the mask frame assembly comprises:
re-adjusting a separation distance between the mask stage and the mask frame by using at least one of the air injection module or the lifting module; and
welding a second mask sheet of the plurality of mask sheets to the mask frame, to be adjacent to the first mask sheet of the plurality of mask sheets.
